(19) United States
(12) Patent Application Publication
(10) Pub. No.: US 2022/0050307 A1
(43) Pub. Date: Feb. 17, 2022

(54) METHOD OF MAKING EYEGLASS LENS

(71) Applicant: SHAPE ENGINEERING GMBH, Köln NRW (DE)

(72) Inventors: Joerg LUDERICH, Ratingen (DE); Christian POEPPERL, Solingen (DE); Michael KREIS, Gruendau (DE); Christian TUSS, Wetzlar (DE); Herger ALT, Lahnau Hessen (DE)

(21) Appl. No.: 17/274,807

(22) PCT Filed: Oct. 25, 2019
(86) PCT No.: PCT/EP2019/079146

§ 371 Date: Apr. 23, 2021

(30) Foreign Application Priority Data
Nov. 5, 2018 (DE) 10 2018 008 669.1

(51) Int. Cl. G02C 7/02; G02C 1/00; G06F 30/10

(52) U.S. Cl. CPC G02C 7/028; G06F 30/10; G02C 1/10

(57) ABSTRACT

The invention relates to a method for producing a spectacle lens, wherein an edge structure is produced on the spectacle lens. The invention is characterized in that expected light effects produced or at least influenced by the edge structure of the spectacle lens, in particular light reflections and/or light transmissions, are ascertained for the spectacle lens with the edge structure, and the ascertained light effects are reduced, in particular in terms of intensity and/or direction and/or color, by applying one or more layers onto the edge structure of the spectacle lens.

The invention relates to a method of making an eyeglass lens having an edge structure. The invention thus also relates to the eyeglass lens made by the method, in particular one with a cross section perpendicular to the optical axis that fits with an eyeglass lens opening of a selected eyeglass frame or with a rimless or partially rimmed glasses corresponds to a selected shape.

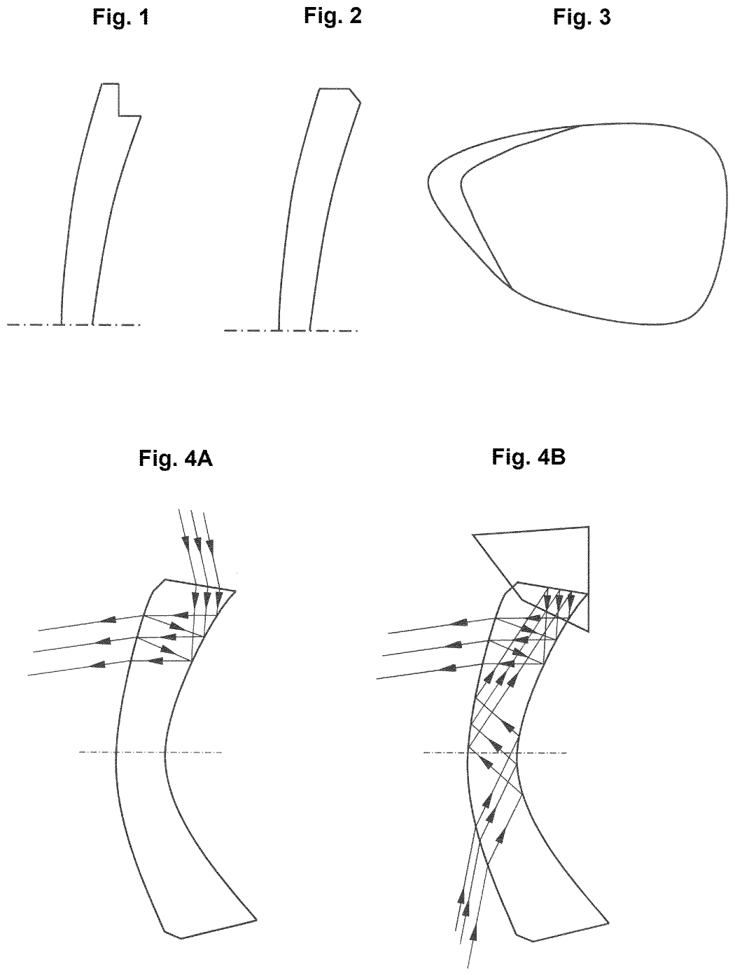

An eyeglass lens with an edge structure is usually made from a lens blank manufactured mostly by edge processing, such as edge grinding of the blank. The term “edge structure” encompasses every possible shape of the manufactured edge of the lens. The eyeglass lens with the edge structure is essentially the ready-to-use lens. In particular, the terms “edge” and “edge structure” are used in the context of this description synonymously, as the edge of a ready-to-use eyeglass lens is structured.

Whereas the front and back faces of an eyeglass lens define the optical properties of the eyeglass lens, it is up to the edge structure of the eyeglass lens to connect, for example to the eyeglass frames or the edge with its edge structure serves purely for defining the lens shape (for example with rimless glasses). The edge structure in the within the scope of this patent application is defined as the structured areas along the edge of an eyeglass lens that are manufactured during the edge processing of the eyeglass lens. In addition to fulfilling the above tasks, an edge structure can also be used, for example, to avoid collisions with the glasses frames (for example shelf “for sports glasses, FIG. 1), to reduce the risk of injury (for example safety bevels, FIG. 2) or to serve aesthetic purposes (for example jewelry facet, FIG. 3).

Even if the edge or the edge structure of an eyeglass lens has no optical effect, its reflection and/or transmission properties can significantly influence the aesthetics of the glasses.

In practice, the following effects among others, are mainly observed or generated by the edge or the edge structure of the eyeglass lenses.
Myopia rings,
Reflection on the back of the facets,
Reflection on the front facet foot,

Light spots on the face through transmission over the edge of the lens; for example for rimless glasses,

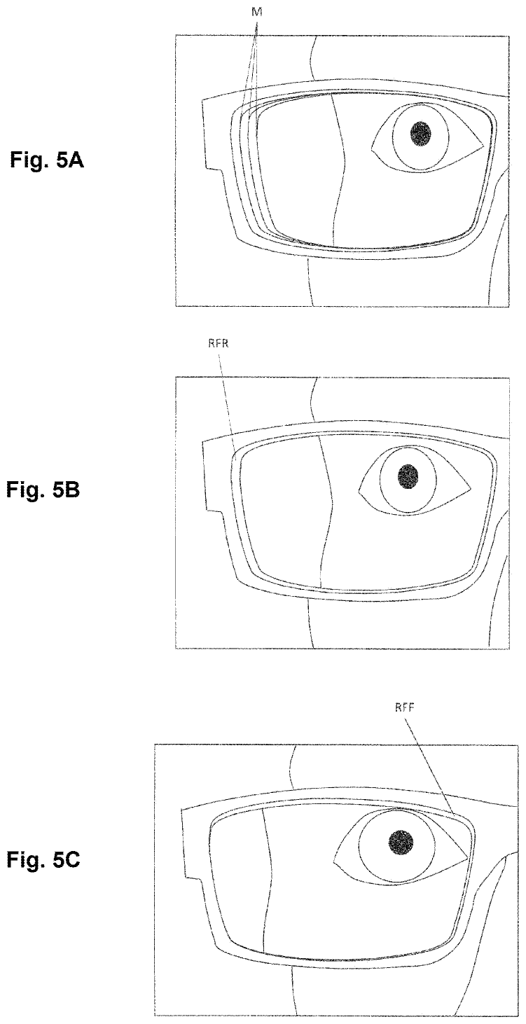

Myopia rings, FIG. 4[A and B], originate from light effects reflected and/or transmitted on the lens edge structure. The light can, for example with rimless glasses, enter the lens interior through the edge or its edge structure, FIG. 4A, or the edge is illuminated from the front through the glass, FIG. 4B. In both cases, the light emanating from the edge is reflected internally in the glass until it is emerges from the front face of the lens. These are particularly evident when looking at the glasses from the side one sees reflections of the edge, FIGS. 5[A-C]. The appearance the glasses and the wearer can be seriously affected. Because this effect is occurs especially in glasses wearers with myopia (nearsightedness), the effect is called myopia rings, shown as myopia rings M in FIG. 5A for an eyeglass lens with −3 dpt.

Full rim glasses are held and centered in the glasses frame by so-called facets. Reflections on the facet are in the form of light or white rings or ring segments visible to the observer. You too can see the appearance of the adversely affect glasses wearer.

FIG. 5B shows reflections RFR on the back of the facet in the case of an eyeglass lens −3 dpt and in FIG. 5C reflections RFF at the front facet foot with an eyeglass lens +9 dpt.

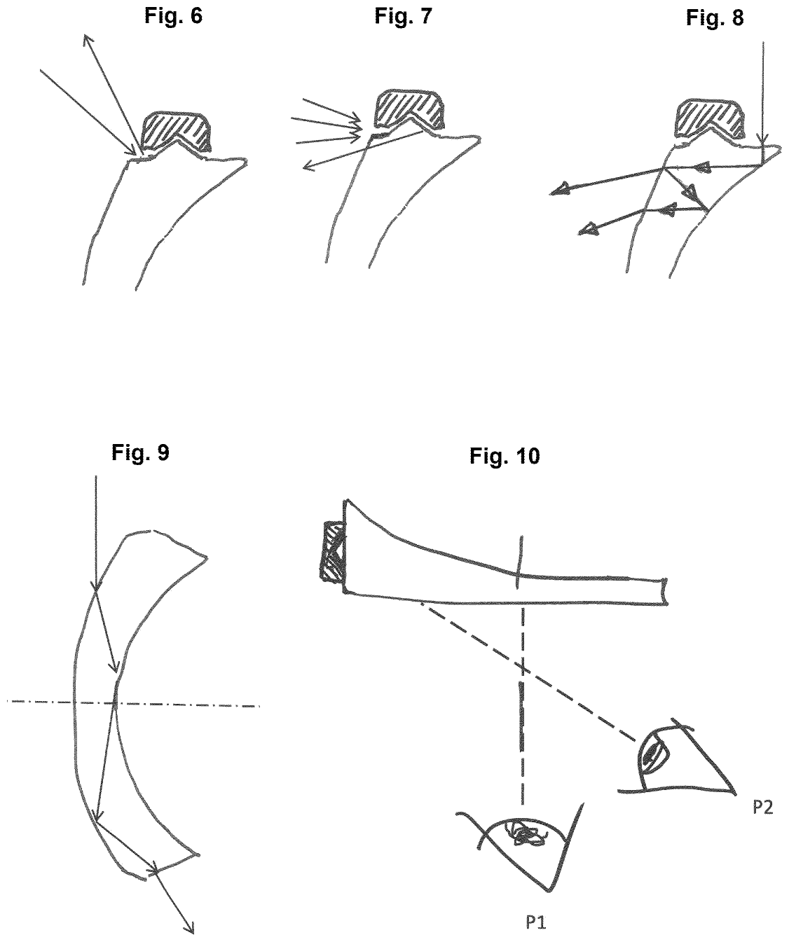

Light effects can be caused by reflections that arise on the outside of the edge structures mot covered by the frames, FIG. 6, or they arise on the inside of the facet, when the outside is covered by the frame, FIG. 7.

If light enters the eyeglass lens from outside via the frame edge, it can, depending on the geometric shape of the eyeglass lens, either exit via the front face, FIG. 8, or, for example with rimless glasses, through the uncovered edge of the glasses. In the first case the reflections are visible to the observer in the eyeglass lens, in the second case bright illuminated areas are seen on the face of the wearer caused by reflections in the lens.

Bright spots on the face of the eyeglass wearer can also be seen with the rimless or half-rim glasses when light enters over the front face and passes in the glass to an exit point on the lens edge, FIG. 9.

The above description illustrates several examples of different light effects seen at the margin or the edge structure of an eyeglass lens, in particular light reflections and/or light transmissions visible to the wearer of glasses and/or to the viewer in or on the glasses or parts of the face of the wearer. In addition to the light effects described, there are other light effects possible by combining the various entry and exit possibilities for light arising in the lens.

In addition, it should be noted that the light effects described are not only created by light, that can exit the lens via the front face, but also via the rear face. In this case, they not only have an impact on the aesthetics, but also affect the visual impression and thus the actual function of the glasses through glare or annoying reflections.

The lighting effects described have been known for many years and different approaches are known to reduce or eliminate the lighting effects described.

The use of anti-reflective coatings on the front and rear faces of the is known in eyeglass lenses. This can also reduce internal reflections. Anti-reflective coatings are widespread today, but do not sufficiently reduce the effects described in many cases.

Tinting the edge after the edge processing by immersing the lens in a dye bath can be used in this context. Either the entire glass or just the edge area is tinted to reduce the light effects. Since color in the optics must always allow transmission, opaque layers are not possible. Furthermore, tinting of the edge is only possible in combination with specifically selected layers of front and back faces. If the entire glass is to be tinted after the edge processing, the layer system must be such on the front and back face (hardcoat, possibly anti-reflective layer, etc.) that the thinning agent can penetrate into these layers and produce the same color as on the uncoated edge area. Should only the edge, but not the front and back faces, they should be treated to not accept the dye.

In the practical implementation, the tinting of the edge is complex, as for every color and glass material its own color bath must be prepared. The procedure is therefore not used in practice or only used in exceptional cases.

The document US 2003/0011742 describes an eyeglass lens with a colored lens rim to minimize the negative effect of the white rings visible from the outside, which by being visible at the foot of the connecting element (pointed facet) on the edge of the glass are generated to reduce or degrade the aesthetics of the glasses. Here one or multi-colored coatings of the glass edge are proposed, which at least partly cover the edge of the lens and match the color of the glasses frame as well as a color which does not match the color of the glasses frame. A process is also described in which these colors are applied to least a portion of the glass edge by colored pencils, brushes, spray or immersion processes.

The cited patent document also describes an automated paint application system that selects a suitable color based on input data or based on a sensor measurement then applies it to the edge of the glass using one of the methods mentioned above. There is no further disclosure of this automated paint application system.

In summary, it can be said that the problems caused by the edge structure of the lenses caused or influenced by light effects, in particular light reflections and light transmission, are known and various approaches to solving this problem have been published. However, there is still no practical solution. The reduction or preferred solution for the lighting effects cannot be done today or only in individual cases unsystematically in a trial-and-error procedure. In particular, in many cases no statement is made as to whether and to what extent disruptive light effects are to be expected and what measures should be taken to optimize the aesthetic impression. A well functioning, economically viable process therefore does not exist, so advice to customers in advance of the production of glasses is not possible or is inadequate.

It is therefore an object of the invention to provide a method of making an eyeglass lens to provide an edge structure, that is to say a ready-to-use eyeglass lens, that is suitable to reduce lighting effects, preferably to avoid entirely those on the edge structure of the eyeglass lenses that originate or are at least influenced by this edge structure.

According to the invention, this object is attained in that the lighting effects to be expected, which are caused or at least influenced by the edge structure of the eyeglass lens, in particular light reflections and/or light transmissions, are determined and the determined light effects are reduced, in particular with regard to their intensity and/or direction and/or color, due to the application of one or more layers on the edge structure of the eyeglass lens.

The at least one layer applied to the edge structure, in particular completely or only a layer applied in some areas to the edge structure, according to the invention ensures that the optical properties of light effects arising on or through the lens edge are changed in such a way that the light effect or effects are at least reduced, preferably eliminated compared to an eyeglass lens without a coating of the edge structure. That is achieved in particular in that the coating extends into the beam path of the light passing through the lens and thus works with the coating to intervene in the generation of the light effects as does the edge structure. In particular, this should cause a desired aesthetic impression to arise from the glasses and the glasses wearer. Furthermore, impairment of the visual impression of the wearer of glasses is reduced by unwanted reflections or light refraction or ideally is prevented entirely.

The main advantage of the invention is that the determination of the expected lighting effects for the edge-structured eyeglass lens can be made before the edge-structured eyeglass lens is manufactured. In this way, the occurrence of light effects can be determined before production and can be reduced or prevented by the coating, especially compared to the same edge-structured eyeglass lens without coating. The coating can preferably be made according to the determined light effect or effects.

For example, a type of coating can be made specifically for a determined light effect. Each of several possible lighting effects can have a different type of assigned coating that is applied to the edge structure.

The invention can preferably provide that the determination of the lighting effects is done theoretically, in particular by a computer-based simulation or a set of tables in dependence on data of the eyeglass lens having the edge structure and/or with the frame provided with the edge structure for the eyeglass lens. So there is no necessity to make the lens beforehand. According to the invention, with a more preferred design it is sufficient that the eyeglass lens with its edge structure and/or the eyeglass lens mount be represented in data. Based on this data, the eyeglass lens, especially simulated in connection with a frame and so also with the simulation determines the occurrence of light effects.

The determination of the light effects can thus be determined dependent on eyeglass lens data and/or, for example frame data, in particular as a function of the glass thickness, preferably the glass thickness at the edge, the glass material, in particular its refractive index, the curvature on the front and back face, the tint and/or the coating and/or depending on the type of frame, the frame shape and/or the frame color. The coating can according to the invention can then influence a determined light effect or several and can affect its intensity, direction and/or color by applying one or more layers to the edge of the eyeglass lenses in such a way that the effect is reduced, preferably eliminated and in particular, create a desired aesthetic impression of the glasses when worn or not.

The influence of the light effects emanating from the edge on the aesthetics due to the inner reflections in the eyeglass lens and the size and position of the edge are significantly influenced. In particular, such internal reflections can be influenced by the coating according to the invention even when this coating is on the outside of the glass edge. For example a coating with a light-absorbing coating agent can be used whose refractive index is equal to or greater, or at least comparable to the refractive index of the lens material. As a result, the total reflection at the boundary layer between the eyeglass lens material and the coating material prevented and the light can overcome the boundary layer and enter the absorbent material where it is absorbed.

For example, myopia rings mainly occur in so-called minus glasses (diverging lenses). Plus glasses (converging lenses) do not show this phenomenon or only in special cases. The general visibility of the myopia rings is strongly direction-dependent in that these light effects are only recognizable for the viewer from a certain viewing angle, FIG. 10. Here myopia rings are not visible in position P1 and visible in position P2. The size of this viewing angle is determined by the reflections taking place in the eyeglass lens and here in particular due to the curvatures of the front and rear faces of the eyeglass lens certainly. A coating according to the invention is therefore particularly suitable for preventing the occurrence of and to reduce or even prevent myopia rings.

The visibility of the myopia rings is still determined by the edge thickness of the lens. This in turn depends on the glass thickness and the size and shape of the glasses frame. Smaller frames generally lead to a thinner frame edge and in turn for reduced visibility of the myopia rings. Higher myopia leads also to larger edge thicknesses with comparable effects. Glasses with a astigmatism or prism correction can be used depending on the angular position of the optical cylinder and the frame shape and have very different edge thickness distributions. Light effects can then occur in unusual places.

According to the invention, the expected effects of eyeglass lens data and/or frame data, in particular of lens material (refractive index) and/or the glass thickness and/or the curvatures of the front and/or back curve and/or the frame shape are determined with the help of the laws of geometric optics. These laws can be implemented in a computer program executing the simulation. In particular, the law of refraction for transmission and reflection, the law of total reflection, the optical law of image and the directed and diffuse reflections take into account reflective behavior. These laws are generally known and can be studied in different textbooks. On the basis of these laws, so-called ray tracing, for example, can be carried out on the basis of the mentioned data. Furthermore, various computer programs are commercially available that provide the precise calculation of the light effects to be expected for a specific lens/frame shape enable. Known optics calculation programs are for example Zemax (Zemax LCC.) or Oslo (Lambda Research Corporation).

The calculations used to carry out the simulation can preferably be used in addition to the above-mentioned data and also take place as a function of the incidence of light. Here it is a good idea to use and assume the lighting conditions that mainly occur in everyday life. Directed and diffuse lighting from above and diffuse lighting from the front are reasonable assumptions for the incidence of light. Furthermore, it is advantageous, especially in some cases, too take into account the shading by the frame and in particular by the upper edge of the frame in the data on the basis of which the simulation is carried out.

On the basis of these simulation calculations it can be determined, for example, to what extent and under which viewing angles myopia rings are structured at a given edge eyeglass lens, in particular in connection with a predetermined frame, will be visible.

With according to the invention actual or simulated application of a coating on the edges structure for treatment of myopia rings, for example the size of the viewing angle without visible myopia rings is an important parameter, FIG. 10.

Experience has shown that angles>45° lead to good results and angles>30° satisfactory impressions. The size of the viewing angle without myopia rings can also be used as important decision criteria for automatic process control, in particular, depending on this criterion, the location of the coating on the edge structure and/or the thickness of the coating can be determined.

In general, according to a further development of the invention, before the actual application of a layer to the edge structure, the application of the layer is simulated in a computer-based manner and then the resulting expected lighting effects are determined by a computer. So the lighting effects can preferably be determined without a layer and with at least one layer on the edge structure of the eyeglass lens and compared with one another.

For example, a user of the simulation program can manually coat areas and/or specify or change layer thicknesses and/or material of the layer and the simulated lighting effects are compared with the layer specified in this way, for example visually using a graphic representation of the light effects, with the simulated light effects without coating.

In this way, the user can determine for himself when the result of the coating is satisfactory and, based on the data representing the simulated coating, make eyeglass lenses with a structured edge and the coating defined in this way. For example, the production data obtained in this way can be sent to a manufacturing machine, in particular transmitted to an edge-processing apparatus and coating system.

Preferably, the simulation of the coating layer and the light effects resulting therefrom can automatically be repeated, in particular until a termination criterion is reached, as for example the minimal intensity of the effect. The computer will thus determine the coating and where it will fail automatically.

The arrangement of the layers determined by the simulation, in particular iterated simulation, can then be made specifically on the lens in order to reduce and even preferably to eliminate the light effects in reality on the eyeglass lens according to the simulation. Automatic data transmission to a manufacturing facility can be provided as described above.

The results obtained in this way can be used, for example, on the one hand to select a suitable coating material as well as to determine the local distribution of the coating material, but also preferably on the other hand to provide the customer with a suitable graphic display program showing the expected appearance of his glasses.

Alternatively, based on the results, it is also possible to make suggestions for well-suited versions, especially for a sensible maximum size of the frame.

If photographs or a 3d scan of the customer's face are available, the information about the expected light effects and suitable frames, also within the framework of a computer-aided customer service.

For example, the invention can provide that the computer-based simulation includes the light effects and/or the edge structure coating as a graphic representation of the light effects, in particular overlain on a pictorial representation of the face of the glasses wearer. This way one can check the effect of the coating on the eyeglass wearer particularly well, especially before the lens is actually manufactured.

The procedure shown for example for “myopia rings” can also be used in an analogous manner for the other cases described above. In these cases one may prefer further parameters, in particular the geometry of the frame, as data in the simulation enter. Depending on the width of the frame edge in combination with the width of the lens edge there may be undesired reflections on the front facet surface (FIG. 6) where more rays of light enter the protruding edge of the glass behind the edge of the frame (FIG. 8). These parameters can be influenced by the appropriate choice of the facet position and can be used in the simulation by taking into account data of a corresponding shadow.

The intensity of the light effects can be influenced by tints and/or coatings on the front and rear panels back faces. These parameters can also be used as data in simulation software and must be taken into account accordingly. While coatings can lead to reduction of internal and external reflections and can damp light effects and change the color impression for the viewer.

In particular, to achieve an optimal aesthetic impression, color and effects can be used that are suitable for the coating. In particular, the color of the frame, the color of the customer's face, the type of frame and the customer's aesthetic choice of color and color combination must be taken into account.

The application of the coating to the edge or the edge structure can be applied over the entire face or on partial areas. In the case of plus glasses, for example, significant lighting effects due to the back of the facet are to be expected, FIG. 7, so it makes sense to only provide this part of the edge with a corresponding layer. As a result, the coating stays with a full rim frame invisible from the outside and, except for the desired reduction or elimination, no change in the light effect can be seen from the outside. In general, according to the invention, only those parts of the edge structure are coated that predominantly affect the effect to be reduced.

Glasses that project beyond the rim of the frame, especially with thick minus lenses with large edge widths, can preferably have a pointed facet with a highly absorbent layer and/or the edge facets in front of and behind the pointed facet with a tinted, partially permeable layer. If the tint is in a skin tone, the protruding edges will be less visible when viewed from the side and the front while light is readily absorbed in the region of the facet covered by the edge of the frame.

According to the invention, coatings with a layer thickness of 20 to 100 μm can be applied, especially if covering colors or a smooth face. Also possible, especially with appropriate pigmentation, to use an opaque layer.

The viscosity and/or surface tension of the preferred coating material to be applied is chosen so that it runs and forms a smooth surface. Furthermore, coatings with the above-mentioned thickness are preferably so highly resilient, that a further protective coating is not necessary and can be dispensed with.

For fitting the eyeglass lenses in the eyeglass frame, the edge processing of the eyeglass lenses are made with a high degree of precision. When layers with the above described thickness values are applied to finished eyeglass lenses, the lenses are too large and in many cases can no longer be fitted into the frame. Therefore, according to the invention, the expected/required layer thickness are determined before the edge processing, in particular this layer thickness or one that depends on it or an equivalent value as a correction value is supplied to the edge processing machine before the mechanical edge processing. The lenses are then smaller than necessary, in particular by the correction value, for example made smaller by the determined layer thickness and only reach the necessary size together with the coating.

A particularly advantageous embodiment of the invention can be achieved if glasses for full-rim frames that require a pointed facet, are provided in a first step by mechanical processing only with a simple flat facet. The flat facet can then be provided with the desired coating. As a replacement for the pointed facet, an elastic, applied centering structure, as is known from de 10 2014 000 107 [U.S. Pat. No. 9,851,584]. The advantages of this process are the simpler coating of the flat facet and the elastic properties of the applied elastic structure. The elastic structure can preferably compensate for size deviations caused by the coating and thus simplifies the production process.

It can be provided in a further development that the elastic, centering structure is tinted with to absorbing pigments. In combination with a tinted, partially permeable layer the same effect as in the solution described above can be achieved.

As an alternative to the described tinted, the partially permeable layers for edge areas of the glass that project beyond the rim of the frame can of course also be of other colors, color combinations or effect colors (for example metallic effect or fluorescent colors).

In order to allow the application of the described invention also in smaller optical companies a set of rules is suggested for use as an alternative to a simulating calculation program or tables. This set of tables describes in particular the relationships for the occurrence of myopia rings by diagrams, tables and/or rules so that even without optical calculations the occurrence and the expected visibility of the myopia rings can be determined. To do this, the geometrical optics are processed in such a way that depending on lens data and/or frame data, such as the lens thickness, the refractive index, the curvature of the front and rear faces as well as the frame size a prediction about the myopia rings is possible or, alternatively, a statement about the frames to be decided on aesthetically.

1. A method of making an eyeglass lens having an edge structure, the method comprising the steps of:
determining expected lighting effects caused or at least influenced by the edge structure of the eyeglass lens; and
reducing the determined lighting effects by applying one or more layers on the edge structure of the lens.

2. The method according to claim 1, wherein the determination of the lighting effects is done theoretically by a computer-based simulation or a set of tables as a function of data of the eyeglass lens having the edge structure and/or data of a frame that receives the eyeglass lens provided with the edge structure.

3. The method according to claim 2, wherein the data are formed by the following information:
the glass thickness,
a geometry of the edge structure,
a lens material,
a curvature of a front and/or rear face, and/or
a degree of coverage of a edge by the frame and/or a frame width, a frame shape, a frame color.

4. The method according to claim 2, further comprising the steps, before applying a layer on the edge structure, of:
simulating the application of the layer in a computer-based manner, and then
determining the resulting lighting effects to be expected using a computer, in particular with comparison to light effects to be expected without applying a layer, preferably the simulation of the layer application and the resulting light effects in an iteration is repeated, in particular until a termination criterion is reached.

5. The method according to claim 2 wherein the data is taken from at least one database.

6. The method according to claim 2, further comprising the step of:
the operator entering at least part of the data manually in a data processing system for implementing a simulation of the lighting effects.

7. The method according to claim 1, wherein the determination of the lighting effects is carried out with the help of the laws of geometric optics.

8. The method according to claim 1, wherein the light effect of the appearance of myopia rings is determined as a function of the viewing angle.

9. The method according to claim 1, wherein, for evaluating the influence of a simulated edge structure coating on the light effect of the occurrence of myopia rings, the viewing angle is used.

10. The method according to claim 1, wherein with light effects caused by the back of a facet of the edge structure, only this part of the edge structure is provided with a layer.

11. The method according to claim 1, wherein in eyeglass lenses with rim widths that project beyond the rim of the frame, only the pointed facet is provided with a light-absorbing, layer, and the edge faces in front of and behind the pointed facet are provided with a tinted, partially translucent layer.

12. The method according to claim 1, wherein the coating has a layer thickness of more than 20 micrometers.

13. The method according to claim 1, wherein the thickness of a layer to be applied to the edge structure, is determined and the determined layer thickness or a dependent/equivalent quantity is taken into account as a correction value when making the edge structure by transmission of a correction value to the edge processing machine before the mechanical edge processing of the eyeglass lens.

14. The method according to claim 1, wherein eyeglass lenses for full-rim frames that require a pointed facet as the edge structure are mechanically machined in a first step without the pointed facet, and only provided in a second step with a flat facet that is provided with the coating as replacement for the pointed facet and, to achieve the required edge structure in a third step, an elastic, centering structure is applied.

15. The method according to claim 14, wherein the elastic, centering structure is colored with absorbent pigments and the centering structure has thereby higher absorption than the layer applied to the flat facet.

16. The method according to claim 2, wherein the computer-based simulation of the lighting effects and/or the edge structure coating includes graphical representation of the lighting effects superimposed on a pictorial representation of a face of a person wearing the eyeglasses.
